(19) United States
(12) Patent Application Publication
(10) Pub. No.: US 2022/0404047 A1
(43) Pub. Date: Dec. 22, 2022

(54) AIRFLOW CONTROL SYSTEM, CONTROL APPARATUS, AIRFLOW CONTROL METHOD AND PROGRAM

(71) Applicant: Nippon Telegraph and Telephone Corporation, Tokyo (JP)

(72) Inventors: Tomomi NAGAO, Musashino-shi, Tokyo (JP); Atsushi Sakurai, Musashino-shi, Tokyo (JP); Yuriko Tanaka, Musashino-shi, Tokyo (JP)

(21) Appl. No.: 17/780,274

(22) PCT Filed: Nov. 29, 2019
(86) PCT No.: PCT/JP2019/046842

§ 371 Date: May 26, 2022

(51) Int. Cl. F24F 11/32; F24F 13/10; H05K 7/20; G06F 1/20

(52) U.S. Cl. CPC F24F 11/32; F24F 13/10; H05K 7/20745; G06F 1/20; F24F 13/068

(57) ABSTRACT

In an airflow control system in a machine room where a plurality of ICT device groups (3a to 3f) is supplied with cold air blown out from a plurality of air conditioners (2a to 2c) an is cooled via an underfloor space, the airflow control system includes a partition that is openable and closable (4a to 4f) provided for each air conditioner in the underfloor space, and a controller that opens, when occurrence of an abnormality is detected in an air conditioner of the plurality of air conditioners, the partition between the air conditioner with the occurrence of the abnormality detected and another air conditioner adjacent to the air conditioner.

### TECHNICAL FIELD

The present invention relates to airflow control in a machine room where a plurality of ICT (Information and Communication Technology) device groups is supplied with cold air blown out from a plurality of air conditioners via an underfloor space and is cooled.

### BACKGROUND ART

Since the ICT device generate heat during operation, the ICT device needs to be cooled to prevent thermal failure. As a cooling method, in a machine room having a free access floor, a method of cooling the ICT device by supplying cold air blown out from an air conditioner to an upper part through a space under the free access floor may sometimes be adopted (NPL 1).

The ICT device is stored in a rack, and a plurality of the ICT devices is often arranged perpendicularly to a front surface of the air conditioner. The longer a row of racks is, the greater a difference in distance from the air conditioner is, and a flow rate of cold air taken into the ICT device varies. Thus, NPL 2 proposes that by providing a partition in the space under the free access floor, the flow rate of cold air is adjusted so that pressure is uniformly generated from near the air conditioner to far from the air conditioner.

### CITATION LIST

### Non Patent Literature

NPL 1: B. Fakhim, “Effect of under-floor blockages and perforated tile openings on the performance of raised-floor data centres,” 17th Australasian Fluid Mechanics Conference, New Zealand, 2010.
NPL 2: S. V. Patankar, “Airflow and Cooling in a Data Center,” Journal of Heat Transfer, 2010.

### SUMMARY OF THE INVENTION

### Technical Problem

As described in NPL 2, the flow rate of cold air can be adjusted by providing the partition in the space under the free access floor. However, in a case of failure of the air conditioner that supplies cold air, the cold air cannot be supplied to a space partitioned by the partition. Even when there is another air conditioner that does not fail in the same floor, it is difficult to receive the supply of cold air from this air conditioner because there is the partition.

The present invention has been made in view of the above points, and an object thereof is to provide a technology that in a machine room where a plurality of ICT device groups is supplied with cold air blown out from a plurality of air conditioners via an underfloor space and is cooled, even upon failure of the air conditioner that supplies the cold air to a space surrounded by a partition, the cold air can be supplied by another air conditioner.

### Means for Solving the Problem

According to the disclosed technology, there is provided an airflow control system in a machine room where a plurality of ICT device groups is supplied with cold air blown out from a plurality of air conditioners via an underfloor space and is cooled, and the airflow control system includes a partition that is openable and closable provided for each air conditioner in the underfloor space and

a controller that opens, when occurrence of an abnormality is detected in an air conditioner of of the plurality of air conditioners, the partition between the air conditioner with the occurrence of the abnormality detected and another air conditioner adjacent to the air conditioner.

### Effects of the Invention

According to the disclosed technology, in the machine room where the plurality of ICT device groups is supplied with cold air blown out from a plurality of air conditioners via the underfloor space and is cooled, even in a case of failure of the air conditioner that supplies the cold air to a space surrounded by the partition, the cold air can be supplied by another air conditioner.

### BRIEF DESCRIPTION OF DRAWINGS

FIG. 1 is a diagram illustrating a configuration example of a machine room in which a rack is disposed according to an embodiment of the present invention.

FIG. 2 is a diagram illustrating a configuration example of the machine room in which a rack is disposed according to the embodiment of the present invention.

FIG. 3 is a plan view of the machine room.

FIG. 4 is a plan view of the machine room.

FIG. 5 is a cross-sectional view of the machine room.

FIG. 6 is a horizontal cross-sectional view of a partition 4a.

FIG. 7 is a diagram for explaining opening and closing of a partition.

FIG. 8 is a diagram for explaining opening and closing of the partition.

FIG. 9 is a diagram for explaining a structural example of a partition roll rotating device.

FIG. 10 is a diagram illustrating a configuration of a partition opening/closing device.

FIG. 11 is a diagram for explaining an example of control by the partition opening/closing device.

FIG. 12 is a diagram illustrating an example of a hardware configuration of the partition opening/closing device.

### DESCRIPTION OF EMBODIMENTS

Hereinafter, embodiments of the present disclosure will be described with reference to the drawings. The embodiment to be described below is merely exemplary, and an embodiment to which the present invention is applied is not limited to the following embodiment.

In the following embodiment, it is envisaged that the present invention is applied to cooling of an ICT device group mounted on a rack. Examples of an ICT device constituting the ICT device group include communication devices such as a switchboard, a switch, and a router, a server, a computer, a patch panel, and a patch panel control robot.

Example of Machine Room First, a basic structure of a machine room and a flow of air in the present embodiment will be described. However, the structure of the machine room to be described here is an example.

In the present embodiment, the ICT device mounted on the rack is cooled by cold air blown out from an air conditioner installed in a machine room having a floor (free access floor) with a free access structure. The free access floor may be referred to as a raised floor. The free access floor may simply be referred to as the “floor”.

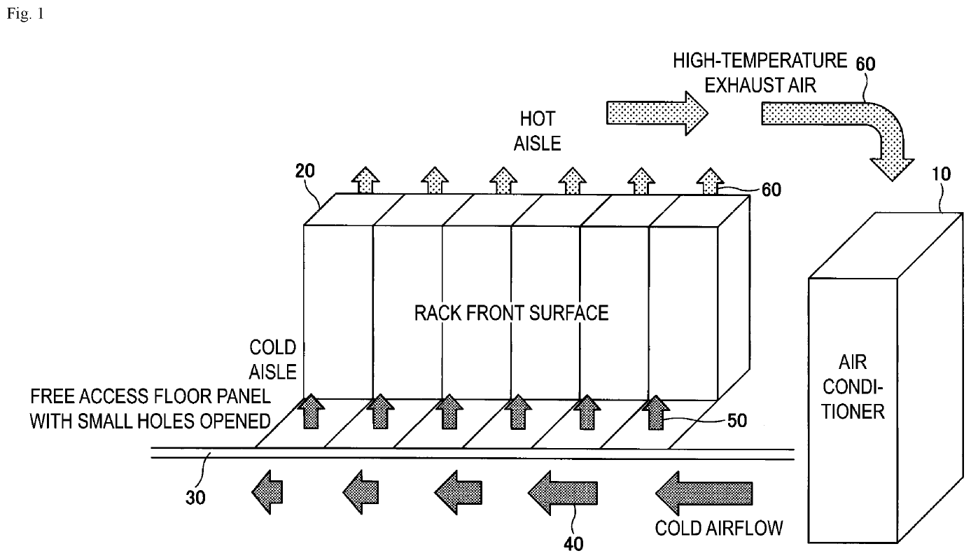

FIG. 1 is a diagram for explaining how air flows in the machine room according to the present embodiment. As illustrated in FIG. 1, in this example, a row of racks 20 on which the ICT device group to be cooled is mounted is installed on a panel 30 of the free access floor with many small holes opened. The row of racks 20 illustrated in FIG. 1 is a group of a plurality of racks (individual racks).

As illustrated, an air conditioner 10 is installed. The air conditioner 10 according to the present embodiment blows cold air under a free access floor in a direction parallel to a front surface of the rack written as “rack front surface” and parallel to a floor surface.

As illustrated in FIG. 1, cold air 40 output from the air conditioner 10 flows under the free access floor (and above building floor) while weakening the momentum with increasing distance from the air conditioner 10, and the cold air 40 rises as cold air 50 on the free access floor from the small hole of the panel 30 of the free access floor. Then, the cold air 50 is sucked to the rack front surface, cools the ICT device group in the rack 20, and is discharged as high-temperature exhaust air 60 from a rack rear surface. The exhaust air 60 is returned to the air conditioner 10.

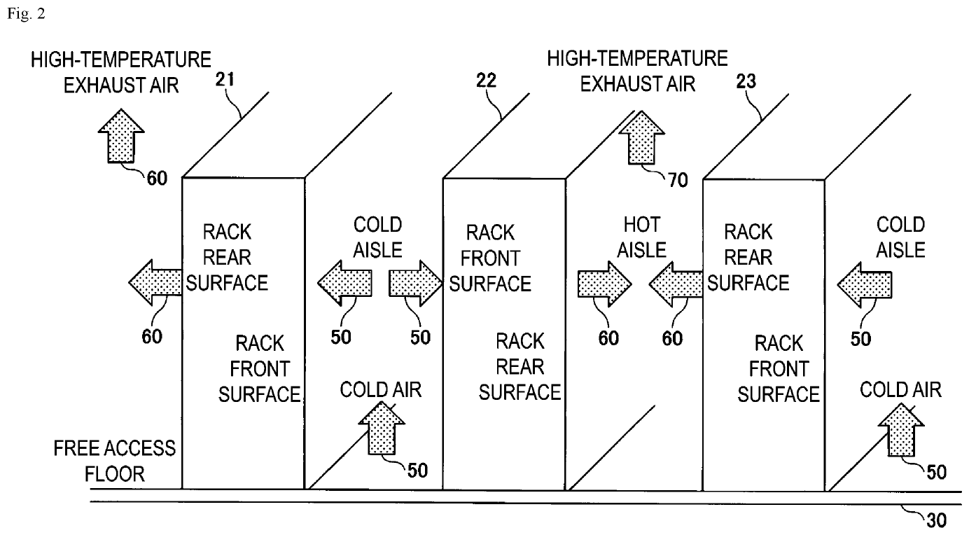

Usually, a plurality of the rows of racks 20 is installed in the machine room; however, to improve air conditioning efficiency, as illustrated in FIG. 2, the plurality of rows of racks is paired with each other and is arranged in parallel so that front surfaces of each pair of rows of racks face each other. In the example of FIG. 2, a front surface of a row of racks 21 and a front surface of a row of racks 22 face each other, and a rear surface of the row of racks 22 and a rear surface of a row of racks 23 face each other. Thus, a cold aisle and a hot aisle as illustrated in FIG. 2 are formed.

### DESCRIPTION OF EMBODIMENT

### Arrangement of Partition

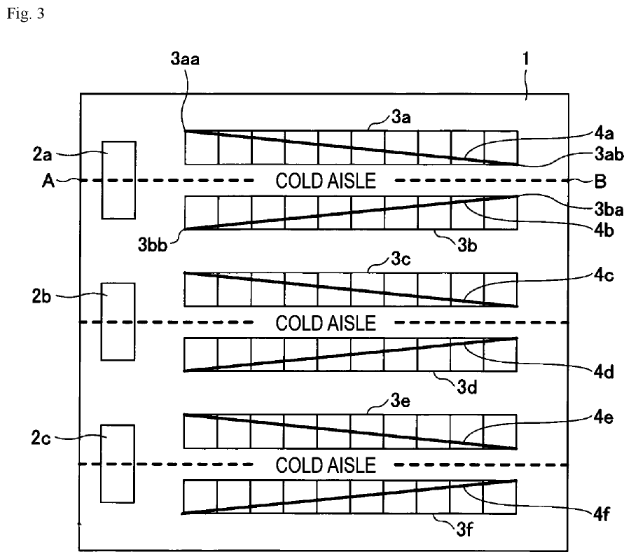

FIG. 3 illustrates a plan view (view seen from above) of the machine room into which partitions 4b to 4f according to the present embodiment are introduced. However, for the partitions 4b to 4f, a space between the free access floor and the building floor is illustrated in cross section taken along a horizontal plane (a plane parallel to the free access floor).

The free access floor is introduced over a floor 1 of the building. As illustrated in FIG. 3, three air conditioners 2a to 2c are installed in the machine room. However, providing three air conditioners is an example, and any number of air conditioners may be provided as long as two or more air conditioners are provided.

In the machine room, six rows of racks 3a to 3f are installed on the free access floor, and each rack of each row of racks is loaded with one or more ICT devices (ICT device group).

As illustrated in FIG. 3, a space between the rows of racks 3a and 3b, a space between the rows of racks 3c and 3d, and a space between the rows of racks 3e and 3f are cold aisles respectively. Each ICT device is placed in the rack such that the cold aisle side is an inlet face.

The dotted lines in FIG. 3 are for illustrating a positional relationship between the air conditioners 2a to 2c and the rows of racks 3a to 3f As illustrated in FIG. 3, it is desirable that a center of an outlet port of the air conditioner 2a is located on an extension line of a center line of the cold aisle between the rows of racks 3a to 3b. The same applies to a positional relationship between the air conditioner 2b and the rows of racks 3c to 3d and a positional relationship between the air conditioner 2c and the rows of racks 3e to 3d.

As illustrated in FIG. 3, partitions 4a to 4f are installed under the row of racks in a space below the free access floor. The partition 4a is installed so as to connect a corner 3aa of the row of racks 3a and a corner 3ab of the row of racks 3a. The corner 3aa of the row of racks 3a is an end point on a side far from the air conditioner 2a of two end points of a short side of the rectangular on a side near the air conditioner 2a when the row of racks 3a is viewed from above. The corner 3ab of the row of racks 3a is an end point on a side near the air conditioner 2a of two end points of a short side of the rectangular on a side far from the air conditioner 2a when the row of racks 3a is viewed from above.

The partition 4b is installed so as to connect a corner 3bb of the row of racks 3b and a corner 3ba of the row of racks 3a. The corner 3bb of the row of racks 3b is an end point on a side far from the air conditioner 2a of two end points of a short side of the rectangular on a side near the air conditioner 2a when the row of racks 3b is viewed from above. The corner 3ba of the row of racks 3b is an end point on a side near the air conditioner 2a of two end points of a short side of the rectangular on a side far from the air conditioner 2a when the row of racks 3b is viewed from above.

As described above, by partitioning a space under the free access floor of a front surface of the air conditioner 2a with the partition from both left and right sides and narrowing an interval between the partitions as a distance from the air conditioner 2a increases, a flow rate of cold air can be adjusted so that pressure is uniformly generated from near the air conditioner 2a to far from the air conditioner 2a.

The rows of racks 3c and 3d and the rows of racks 3e and 3f are also installed with the partitions 4c and 4d, and the partitions 4e and 4f respectively, in the same manner as the rows of racks 3a and 3b. That is, the partitions 4b to 4f are also installed so as to connect the corners of the corresponding row of racks to each other.

Since a rack pedestal is always provided just below an end of a row of racks, the arrangement of the partition as described above makes it easier to understand the installation position of the partition.

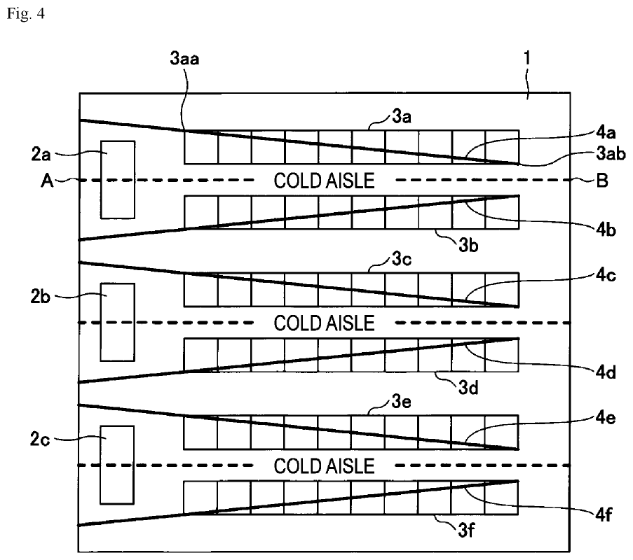

The partitions 4a to 4f may be installed extending not only in a range of the row of racks but also to a wall on the side of the air conditioners 2a to 2c. FIG. 4 is a plan view of a case where the partition is extended.

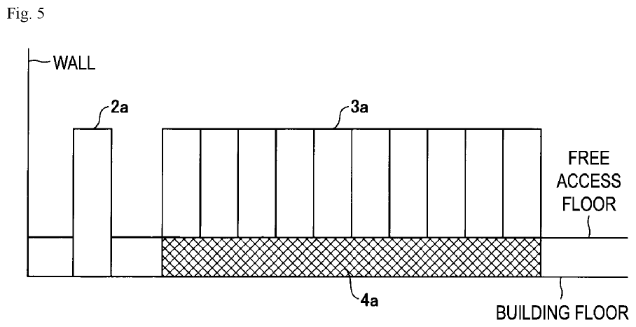

FIG. 5 is a cross-sectional view of the machine room taken along a vertical plane indicated by a line A-B illustrated in FIG. 3. As illustrated in FIG. 5, the partition 4a is disposed below the row of racks 3a in a space on the front surface of the air conditioner 2a. In a cross section corresponding to FIG. 4, in FIG. 5, the partition 4a extends to the wall on the air conditioner 2a side.

The partition arrangement as illustrated in FIGS. 3 and 4 is an example. For example, one partition may be provided each between two adjacent air conditioners.

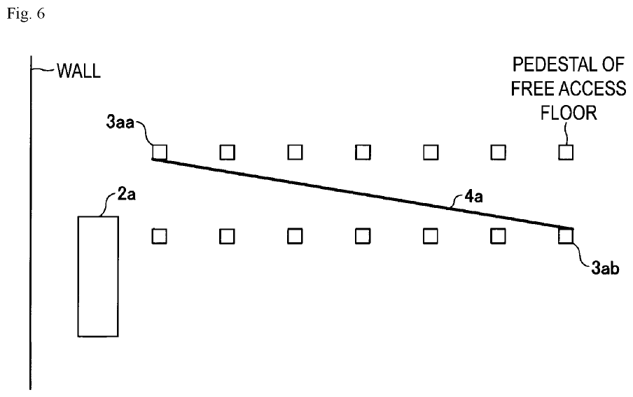

FIG. 6 is a cross-sectional view of a space between the free access floor and the building floor of a portion in which the row of racks 3a illustrated in FIG. 3 is disposed taken along a horizontal plane. As illustrated in FIG. 6, a plurality of pedestals that support the free access floor is illustrated, and the partition 4a is installed to connect a pedestal at a position indicated by 3aa and a pedestal at a position indicated by 3ab. In the cross section corresponding to FIG. 4, in FIG. 6, the partition 4a extends to the wall on the air conditioner 2a side.

In the following description, when a to f are described without distinction, components may not be denoted by a to f, like “partition 4”, for example.

Structure of Partition

The material of the partition 4 is a material having non-flammable and insulating properties. Since an electric power cable and a communication cable may be arranged in a space under the free access floor, the material of the partition 4 is preferably a flexible material so that a gap is not created even when the partition 4 covers the cables.

On the other hand, when the flow rate of the air conditioner 2 is strong as the partition 4 is soft, the partition 4 is more likely to be turned up, and therefore, a weight may be fixed to a lower end of the partition 4. In this case, a weight within withstand load of the partition roll rotating device 5, which will be described later, is used.

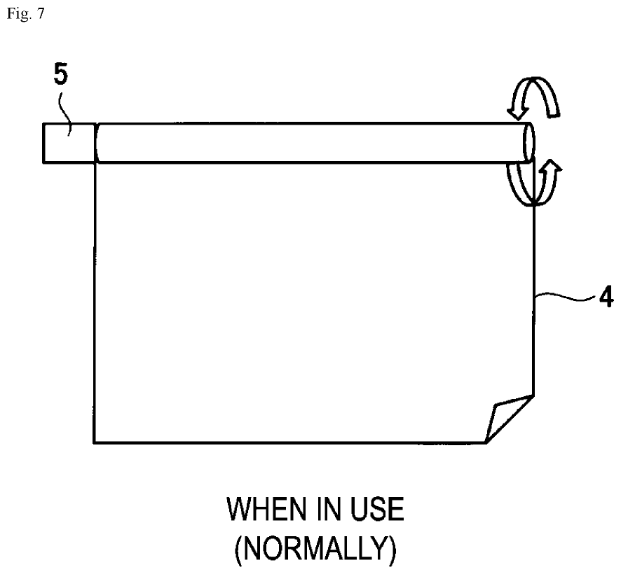

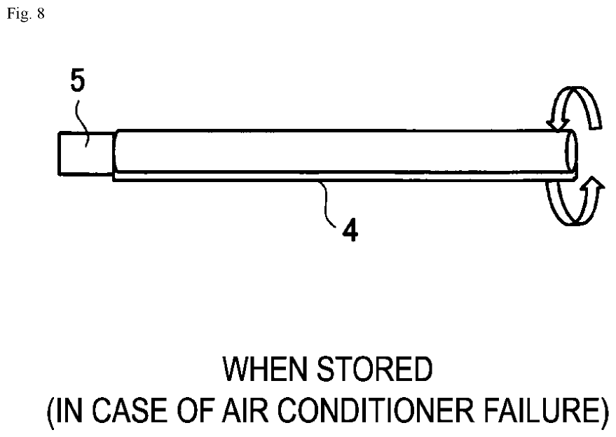

As illustrated in FIGS. 7 and 8, the partition 4 according to the present embodiment is used by being attached to the partition roll rotating device 5. The partition roll rotating devices 5a, 5b, 5c, 5d, 5e, and 5f have the partitions 4a, 4b, 4c, 4d, 4e, and 4f, respectively.

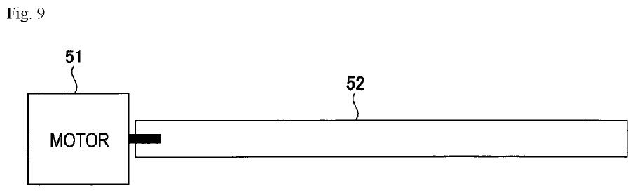

FIG. 9 illustrates a configuration example of the partition roll rotating device 5 in a case where the partition 4 is not attached. As illustrated in FIG. 9, the partition roll rotating device 5 includes a motor 51 and a cylindrical partition attachment portion 52. The partition 4 is attached to the partition attachment portion 52. Hereinafter, the partition is attached to the “partition roll rotating device 5”.

In the partition roll rotating device 5, a state (during use) in which the partition 4 is exposed is illustrated in FIG. 7. FIG. 8 illustrates a state (during storage) in which the partition 4 is wound by rotating the partition attachment portion 52 in the partition roll rotating device 5. The state in which the partition 4 is wound may be referred to as an open state of the partition 4.

A method of attaching the partition roll rotating device 5 under the free access floor may be any method. For example, in the example illustrated in FIG. 6, there is a method of attaching the partition roll rotating device 5 to the pedestal at the position of 3aa and the pedestal at the position of 3ab. The partition roll rotating device 5 may be attached to a back surface of the free access floor.

Opening and Closing Control of Partition

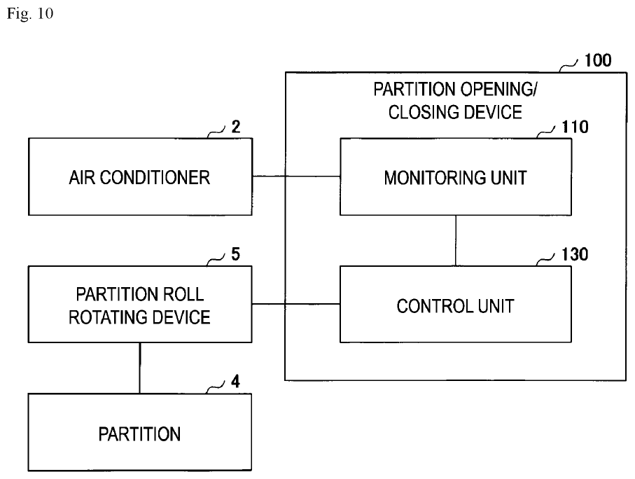

Opening and closing control of the partition according to the present embodiment will be described. FIG. 10 is a configuration diagram of a system that performs the opening and closing control of the partition.

As illustrated in FIG. 10, this system includes a partition opening/closing device 100 and the partition 4. The partition opening/closing device 100 may be referred to as a controller. The partition device 100 may be provided inside or outside the machine room. The partition device 100 may be provided on the cloud. In the partition device 100, a plurality of machine rooms may be control targets. When the partition device 100 is provided in the machine room, the partition device 100 may be attached to one rack.

The partition opening/closing device 100 includes a monitoring unit 110 and a control unit 130. The monitoring unit 110 is connected to each air conditioner (2a to 2c) and monitors operating conditions of the air conditioning facilities 2a to 2c.

The control unit 130 is connected to each partition roll rotating device (5a to 5f), controls the partition rotating device 5 in accordance with the operating condition of the air conditioner 2, and opens and closes the partition 4.

More specifically, when an abnormality of operation is detected in any of the air conditioners 2 by monitoring by the monitoring unit 110, the control unit 130 transmits a signal for storing the partition 4 between the air conditioner 2 in which the abnormality has been detected and another air conditioner 2 adjacent to the air conditioner 2 in which the abnormality has been detected to the partition roll rotating device 5 including the partition 4. The partition roll rotating device 5 having received the signal rotates the partition attachment portion 52 to store the exposed partition 4.

For example, in the partition arrangement illustrated in FIG. 3, the partition 4 between the air conditioner 2 in which an abnormality has been detected and another air conditioner 2 adjacent to the air conditioner 2 in which the abnormality has been detected is the partition 4 between a space on a front surface of the air conditioner 2 in which the abnormality has been detected and a space on a front surface of another air conditioner 2 adjacent to the air conditioner 2 in which the abnormality has been detected in the space under the free access floor.

The control unit 130 is provided with a database that stores data indicating a positional relationship of the air conditioners 2a to 2c, the rows of racks 3a to 3f, and the partitions 4a to 4f in the machine room to be controlled, and with reference to the database, the control unit 130 can grasp in which partition the partition 4 between the air conditioner 2 in which an abnormality has been detected and another air conditioner 2 adjacent to the air conditioner 2 in which the abnormality has been detected is.

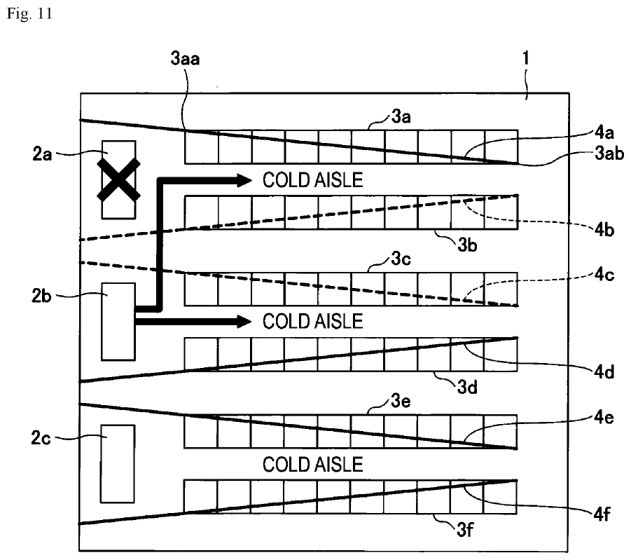

A specific example of the opening and closing control of the partition will be described with reference to FIG. 11. As illustrated in FIG. 11, it is assumed that the air conditioner 2a has failed. The monitoring unit 110 of the partition opening/closing device 100 detects that the air conditioner 2a has failed and notifies the control unit 130 of the failure.

The control unit 130 determines that the partition between the air conditioner 2a in which an abnormality has been detected and the air conditioner 2b adjacent to the air conditioner 2a is the partition 4b or 4c. Then, the control unit 130 transmits a signal indicating that the partition is stored to each of the partition roll rotating devices 5b having the partition 4b and the partition roll rotating device 5c having the partition 4c. As a result, the partitions 4b and 4c are open, and cold air to the ICT device group mounted on the rack row 3a and the row of racks 3b is supplied from the air conditioner 2b.

In the example of FIG. 11, as a result, the air conditioner 2b cools all ICT device groups mounted in the rows of racks 3a to 3d.

If it is known in advance that an amount of heat generated by the ICT device group is too large to cover with an air conditioning capacity of the air conditioner 2 adjacent to the failed air conditioner 2, the control unit 130 may transmit a signal to the partition roll rotating device 5 so that not only the partition between the failed air conditioner 2 and the adjacent air conditioner 2, but also a further partition is stored. In the example of FIG. 11, control is performed to store the partitions 4d and 4e in addition to the partitions 4b and 4c.

In the example illustrated in FIG. 11, if the air conditioner 2b has failed instead of the air conditioner 2a, there are two air conditioners adjacent to the air conditioner 2b, which are the air conditioner 2a and the air conditioner 2c. In this case, for example, the control unit 130 may select the air conditioner in which the margin of the air conditioning capacity is larger of the two air conditioners and may perform control to store the partition between the failed air conditioner 2b and the selected air conditioner (2a or 2c).

In addition, as described above, when the air conditioning capacity cannot be covered by only the adjacent air conditioner (2a or 2c), the partitions 4b and 4c between the failed air conditioner 2b and the air conditioner 2a, and the partitions 4d and 4e between the failed air conditioner 2b and the air conditioner 2c may be stored.

For “the margin of the air conditioning capacity” described above, when a certain air conditioner A sufficiently cools 50 ICT devices and has the ability to sufficiently cool additional 50 ICT devices and another air conditioner B sufficiently cools 50 ICT devices and has the ability to sufficiently cool additional 10 ICT devices, the margin of the air conditioner A is larger than the margin of the air conditioner B.

Hardware Configuration Example

The partition opening/closing device 100 can be implemented by causing a computer to execute a program describing details of processing as described in the present embodiment. The “computer” may be a physical machine or a virtual machine. When a virtual machine is used, “hardware” described here is virtual hardware.

The partition opening/closing device 100 can be implemented by executing a program corresponding to processing performed by the partition opening/closing device 100 by using hardware resources such as a CPU and a memory mounted in a computer. The program can be recorded on a computer-readable recording medium (a portable memory or the like) to be stored or distributed. The program can also be provided via a network such as the Internet or an electronic mail.

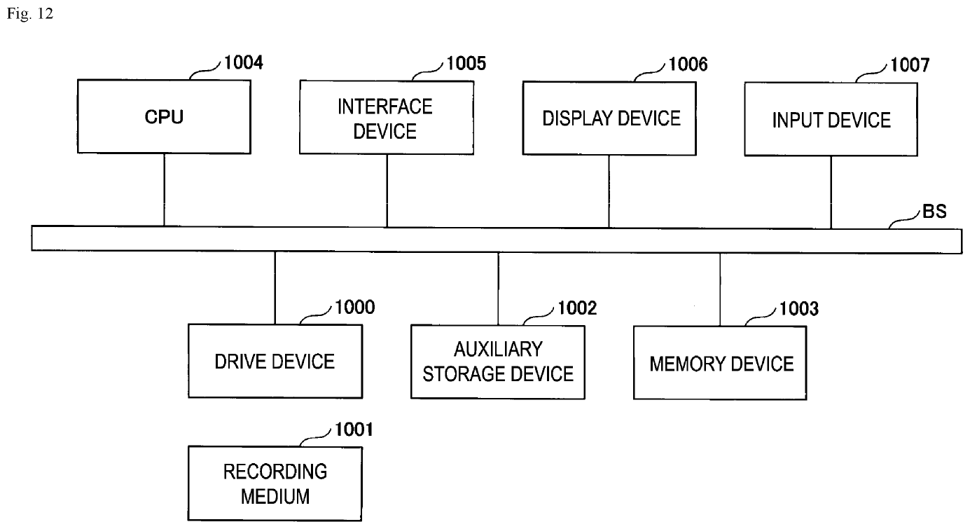

FIG. 12 is a diagram illustrating an example of a hardware configuration of the above-described computer. The computer in FIG. 12 includes a drive device 1000, an auxiliary storage device 1002, a memory device 1003, a CPU 1004, an interface device 1005, a display device 1006, an input device 1007, and the like which are connected to each other through a bus B.

A program for implementing processing in the computer is provided by, for example, a recording medium 1001 such as a CD-ROM or a memory card. When the recording medium 1001 that stores a program is set in the drive device 1000, the program is installed in the auxiliary storage device 1002 from the recording medium 1001 via the drive device 1000. Here, the program may not necessarily be installed from the recording medium 1001 and may be downloaded from another computer via a network. The auxiliary storage device 1002 stores the installed program and also stores necessary files, data, and the like.

The memory device 1003 reads the program from the auxiliary storage device 1002 and stores the program in a case where an instruction to start the program is given. The CPU 1004 performs functions related to the partition opening/closing device 100 in accordance with the program stored in the memory device 1003. The interface device 1005 is used as an interface for connection to a network. The display device 1006 displays a graphical user interface (GUI) or the like according to a program. The input device 1007 is constituted by a keyboard, a mouse, buttons, a touch panel, or the like, and is used to input various operation instructions.

### Effects of Embodiment

According to the present embodiment described above, by installing the partition in the space under the free access floor, it is possible to efficiently cool the ICT device, and since the partition is automatically stored when the air conditioner has failed, the ICT device group that has been covered by the failed air conditioner before the failure can be cooled by another air conditioner. Thus, a risk of failure of the ICT device can be reduced.

### Summary of Embodiment

The present specification describes at least an airflow control system, a controller, an airflow control method, and a program of each of the following items.

### Item 1

An airflow control system in a machine room where a plurality of ICT device groups is supplied with cold air blown out from a plurality of air conditioners and cooled via an underfloor space, the airflow control system including:

a partition that is openable and closable provided for each of the plurality of air conditioners in the underfloor space; and

a controller configured to open, when occurrence of an abnormality in an air conditioner of the plurality of air conditioners is detected, the partition between the air conditioner with the occurrence of the abnormality detected and another air conditioner of the plurality of air conditioners adjacent to the air conditioner.

### Item 2

The airflow control system according to item 1, wherein

the partition is provided along a diagonal line under a row of a plurality of racks in the underfloor space on a front surface of an air conditioner of the plurality of air conditioners.

### Item 3

The airflow control system according to item 1 or 2, wherein

when an air conditioning capacity is insufficient by only opening the partition between the air conditioner with the occurrence of the abnormality detected and the other air conditioner adjacent to the air conditioner, the controller further opens another partition.

### Item 4

The airflow control system according to any one of items 1 to 3, wherein

when there are two air conditioners of the plurality of air conditioners adjacent to the air conditioner with the occurrence of the abnormality detected, the controller selects an air conditioner having a larger margin of the air conditioning capacity of the two air conditioners and opens the partition between the air conditioner with the occurrence of the abnormality detected and the air conditioner selected.

### Item 5

A controller that controls a partition that is openable and closable provided for each of a plurality of air conditioners in an underfloor space in a machine room where a plurality of ICT device groups is supplied with cold air blown out from a plurality of air conditioners via the underfloor space and is cooled, the controller including:

a monitoring unit configured to monitor each of the plurality of air conditioners; and

a control unit configured to open, when the monitoring unit detects occurrence of an abnormality in an air conditioner of the plurality of air conditioners, the partition between the air conditioner with the occurrence of the abnormality detected and another air conditioner of the plurality of air conditioners adjacent to the air conditioner.

### Item 6

The controller according to item 5, wherein

when an air conditioning capacity is insufficient by only opening the partition between the air conditioner with the occurrence of the abnormality detected and the other air conditioner adjacent to the air conditioner, the control unit further opens another partition.

### Item 7

An airflow control method executed by a controller that controls a partition that is openable and closable provided for each of a plurality of air conditioners in an underfloor space in a machine room where a plurality of ICT device groups is supplied with cold air blown out from a plurality of air conditioners via the underfloor space and is cooled, the airflow control method including:

monitoring each of the plurality of air conditioners; and

opening, when occurrence of an abnormality in an air conditioner of the plurality of air conditioners is detected by the monitoring, the partition between the air conditioner with the occurrence of the abnormality detected and another air conditioner adjacent to the air conditioner.

### Item 8

A program for causing a computer to operate as an individual unit in the controller according to item 5 or 6.

Although the present embodiment has been described above, the present invention is not limited to such a specific embodiment, and various modifications and changes can be made within the scope of the gist of the present invention described in the claims.

### REFERENCE SIGNS LIST

10 Air conditioner
20 Row of racks
30 Panel of free access floor
1 Building floor
2a to 2c Air conditioner
3a to 3f Row of racks
4a to 4f Partition
5a to 5f Partition roll rotating device
51 Motor
52 Partition attachment portion
100 Partition opening/closing device
110 Monitoring unit
130 Control unit
1000 Drive device
1001 Recording medium
1002 Auxiliary storage device
1003 Memory device
1004 CPU
1005 Interface device
1006 Display device
1007 Input device

1. An airflow control system in a machine room where a plurality of ICT device groups is supplied with cold air blown out from a plurality of air conditioners via an underfloor space, the airflow control system comprising:
a partition that is openable and closable provided for each of the plurality of air conditioners in the underfloor space; and
a controller configured to open, when occurrence of an abnormality in an air conditioner of the plurality of air conditioners is detected, the partition between the air conditioner with the occurrence of the abnormality detected and another air conditioner of the plurality of air conditioners adjacent to the air conditioner.

2. The airflow control system according to claim 1, wherein
the partition is provided along a diagonal line under a row of a plurality of racks in the underfloor space on a front surface of an air conditioner of the plurality of air conditioners.

3. The airflow control system according to claim 1, wherein
when an air conditioning capacity is insufficient by only opening the partition between the air conditioner with the occurrence of the abnormality detected and the other air conditioner adjacent to the air conditioner, the controller further opens another partition.

4. The airflow control system according to claim 3, wherein
when there are two air conditioners of the plurality of air conditioners adjacent to the air conditioner with the occurrence of the abnormality detected, the controller selects an air conditioner having a larger margin of the air conditioning capacity of the two air conditioners and opens the partition between the air conditioner with the occurrence of the abnormality detected and the air conditioner selected.

5. A controller that controls a partition that is openable and closable provided for each of a plurality of air conditioners in an underfloor space in a machine room where a plurality of ICT device groups is supplied with cold air blown out from a plurality of air conditioners via the underfloor space, the controller comprising:
a monitoring unit, including one or more processors, configured to monitor each of the plurality of air conditioners; and
a control unit, including one or more processors, configured to open, when the monitoring unit detects occurrence of an abnormality in an air conditioner of the plurality of air conditioners, the partition between the air conditioner with the occurrence of the abnormality detected and another air conditioner of the plurality of air conditioners adjacent to the air conditioner.

6. The controller according to claim 5, wherein
when an air conditioning capacity is insufficient by only opening the partition between the air conditioner with the occurrence of the abnormality detected and the other air conditioner adjacent to the air conditioner, the control unit further opens another partition.

7. An airflow control method executed by a controller that controls a partition that is openable and closable provided for each of a plurality of air conditioners in an underfloor space in a machine room where a plurality of ICT device groups is supplied with cold air blown out from a plurality of air conditioners via the underfloor space, the airflow control method comprising:
monitoring each of the plurality of air conditioners; and
opening, when occurrence of an abnormality in an air conditioner of the plurality of air conditioners is detected by the monitoring, the partition between the air conditioner with the occurrence of the abnormality detected and another air conditioner adjacent to the air conditioner.

8. A program for causing a computer to operate as an individual unit in the controller according to claim 5.

9. The airflow control method according to claim 7, further comprising:
when an air conditioning capacity is insufficient by only opening the partition between the air conditioner with the occurrence of the abnormality detected and the other air conditioner adjacent to the air conditioner, opening another partition.

10. The airflow control method according to claim 9, further comprising:
when there are two air conditioners of the plurality of air conditioners adjacent to the air conditioner with the occurrence of the abnormality detected, the controller selects an air conditioner having a larger margin of the air conditioning capacity of the two air conditioners and opens the partition between the air conditioner with the occurrence of the abnormality detected and the air conditioner selected.

10. The airflow control method according to claim 7, wherein
the partition is provided along a diagonal line under a row of a plurality of racks in the underfloor space on a front surface of an air conditioner of the plurality of air conditioners.
